(19) United States
(12) Patent Application Publication
(10) Pub. No.: US 2009/0241681 A1
(43) Pub. Date: Oct. 1, 2009

(54) HYDROGEL-BASED MEMS BIOSENSOR

(76) Inventors: Andrew Machauf, Wardon (IL); Ariel Cohen, Givat Yearin (IL)

Correspondence Address: COOL PATENT, P.C.;c/o CPA Global, P.O. BOX 52050, MINNEAPOLIS, MN, 55402, US

(21) Appl. No.: 12/056,771

(22) Filed: Mar. 27, 2008

(51) Int. Cl. G01B 7/16; H01L 21/00

(52) U.S. Cl. 73/777; 438/49; 257/E21.002

(57) ABSTRACT

A biosensor using a stress sensor, such as a FET device or a piezoresistive device, embedded in a MEMS structure and coated with hydrogel is provided. The MEMS structure comprises any structure with a flexible portion and may include a cantilever, beam, or plate. When the hydrogel swells due to the presence of an analyte, the hydrogel imparts stress on the MEMS structure which is then detected by the embedded stress sensor. A passivation layer may be included in between the MEMS structure and the hydrogel. The MEMS structure may further be coated with a second hydrogel.

### BACKGROUND

Biosensors are devices that can detect an analyte by using a biological component with a physicochemical detector component. The devices may use various techniques, but often have drawbacks in detection. For example, biosensing based on photoluminescence is time-consuming and costly as it requires probe molecules and optical detection equipment. The devices based on field effect such as FET-like transistors and silicon nanowires suffer from high current drifts and chemical instability of silicon. Capacitive sensing has similar drawbacks.

### BRIEF DESCRIPTION OF THE DRAWINGS

The claimed subject matter will be understood more fully from the detailed description given below and from the accompanying drawings of disclosed embodiments which, however, should not be taken to limit the claimed subject matter to the specific embodiment(s) described, but are for explanation and understanding only.

FIG. 1 shows a biosensor according to one embodiment.

FIG. 2 is a flowchart of a method of constructing a biosensor according to one embodiment.

FIG. 3 is a pictorial depiction of the formation of a passivation layer on a biosensor according to one embodiment.

FIG. 4 is a pictorial depiction of the attachment of a hydrogel to a biosensor according to one embodiment.

FIG. 5 is depiction of a biosensor with an analyte present according to one embodiment.

FIG. 6 shows a biosensor according to another embodiment.

FIG. 7 shows the top view of a biosensor according to yet another embodiment.

FIG. 8 shows a biosensor according to yet another embodiment.

FIG. 9 shows a biosensor according to yet another embodiment.

### DETAILED DESCRIPTION

According to one or more embodiments, a biosensor is provided as a highly sensitive device for detection of an analyte. As used herein, “biosensor” refers to a device configured to detect a biological component with a detector element, and “analyte” refers to any chemical or biological constituent undergoing analysis and may include any detectable condition or molecule.

Non-limiting examples of analytes include an amino acid, peptide, polypeptide, protein, glycoprotein, lipoprotein, antibody, nucleoside, nucleotide, oligonucleotide, nucleic acid, sugar, carbohydrate, oligosaccharide, polysaccharide, fatty acid, lipid, hormone, metabolite, growth factor, cytokine, chemokine, receptor, neurotransmitter, antigen, allergen, antibody, substrate, metabolite, cofactor, inhibitor, drug, pharmaceutical, nutrient, prion, biohazardous agent, infectious agent, prion, vitamin, heterocyclic aromatic compound, carcinogen, mutagen and/or waste product. “Analytes” are not limited to single molecules or atoms, but may also comprise complex aggregates, such as a virus, bacterium, Salmonella, Streptococcus, Legionella, E. coli, Giardia, Cryptosporidium, Rickettsia, spore, mold, yeast, algae, amoebae, dinoflagellate, unicellular organism, pathogen, cell, etc. Virtually any chemical or biological compound, molecule or aggregate could be a target analyte, and the scope of the claimed subject matter is not limited in this respect.

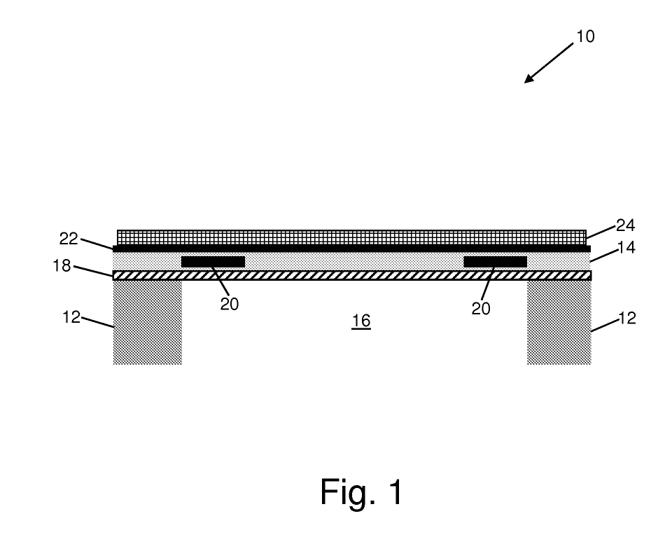

Referring to FIG. 1, a biosensor is shown according to one embodiment at 10. Note that the figures herein are not drawn to scale and are for purposes of example and discussion. Biosensor 10 includes one or more support structures such as pillars 12 for supporting a microelectromechanical systems (MEMS) structure 14. Supporting the MEMS structure 14 may include clamping or other means as long as the support structures are configured to allow deflection in the MEMS structure 14. Support structures 12 are not required to be of any particular shape or size. For example, the height of the support structures may vary based on implementation. The pillars 12 may be created by etching a cavity 16, thereby leaving pillars 12 remaining. Alternatively, the pillars may be separately constructed and attached, and the scope of the claimed subject matter is not limited in these respects.

In one or more embodiments, the MEMS structure 14 may be fabricated using a silicon-on-insulator (SOI) wafer which is made of layered silicon-insulator-silicon substrate locally ending with a bottom layer of buried oxide 18. It should be noted that the bottom layer of buried oxide 18 may be separately constructed from the SOI wafer. Nitride, oxinitride, and other materials may be used in lieu of or in addition to oxide. For fabrication of the MEMS structure, other suitable materials such as polymers, metals, and other semiconductor compounds may also be used. Further, due to their relatively smaller size, MEMS structures may be fabricated using nanoscale and/or microscale technology, which may include deposition, etching, photolithography, micromachining, etc., and the scope of the claimed subject matter is not limited in these respects.

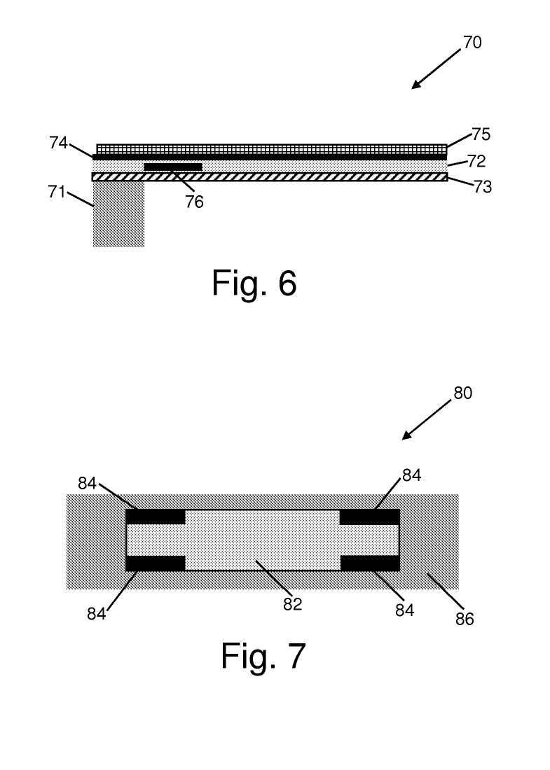

As shown, MEMS structure 14 comprises a beam which may be supported at both ends by pillars 12. In general, a MEMS structure 14 may be inclusive of any structure with a flexible portion capable of deflection. For example, MEMS structure 14 may include a very thin diaphragm capable of behaving as a membrane and a very thin beam capable of behaving as a string. Other such structures may include a cantilever which is supported only at one end and/or a plate which is supported from three or more or all sides or corners or other support points. Such alternative embodiments are later shown in and described in FIGS. 6-7, below.

MEMS structure 14 includes at least one embedded stress sensor 20 for detecting deflection in the MEMS structure, and may include two or more stress sensors 20 in alternative embodiments. As such, the stress sensor 20 may be located at a region in the MEMS structure 14 that is load-bearing. As an example, higher stress-bearing locations include being in close proximity to the support structures such as pillars 12. Generally, higher stress-bearing locations provide suitable sensor readings. Alternatively, the stress sensor 20 may be situated in other stress-bearing locations on the MEMS structure 14. Additional stress sensors 20 located at different stress-bearing locations may also be used, and the scope of the claimed subject matter is not limited in this respect.

Suitable stress sensors 20 capable of being embedded in the MEMS structure 14 include field-effect transistor (FET) devices and/or piezoresistive devices. FET devices may include a metal-oxide-silicon field-effect transistor (MOSFET), an insulated-gate field-effect transistor (IGFET) which may have a gate insulator that is not an oxide, a polysilicon-oxide-silicon field-effect transistor, and/or other transistor devices made of semiconductor materials other than silicon. Piezoresistive devices are sensors with elements which change their conductivity as a function of stress applied upon them. As non-limiting examples, such elements may include quartz, ceramic, metals, germanium, polycrystalline silicon, amorphous silicon, silicon carbide, and single crystal silicon. Piezoresistive devices may include piezomagnetic devices, piezoelectric devices, and other such devices. Stress on the MEMS structure 14 is capable of modulating such FET device or piezoresistive device conductivity. The resulting modulated conductivity in response to the deflection of MEMS structure 14 may be utilized to generate a conductivity signal that is representative of the amount of stress which MEMS structure 14 undergoes. As a result, in one or more embodiments the conductivity signal may be proportional, or nearly proportional, to the amount of deflection of MEMS structure 14. The conductivity signal may be fed by electrical wires or by other means to on-chip and/or off-chip electronics for information processing of the conductivity signal. Such detection and processing of an electrical signal generated by stress sensors 20 may be performed by suitable analog and/or digital circuits, such as a processor, as is generally known to those of skill in the electrical arts. For example, the conductivity signal may be fed into a comparator circuit to provide an indication that MEMS structure 14 has deflected an amount equal to or greater than a threshold amount to indicate the presence of a threshold amount of analyte. Alternatively, an analog-to-digital converter (ADC) type circuit may receive the conductivity signal to produce a digital signal having a value indicative of the amount of deflection of MEMS structure 14 so that the digital signal may be read and/or processed by other digital circuits such as a processor or the like. Many other examples of detection and/or signal processing circuits may be utilized, and the scope of the claimed subject matter is not limited in these respects. Other electronic stress sensors 20 capable of detecting deflection in the MEMS structure may be embedded in MEMS structure 14, and the scope of the claimed subject matter is not limited in these respects.

Biosensor 10 may further include a passivation layer 22 located on the MEMS structure 14 for protecting the MEMS structure, the embedded stress sensor(s) 20, and/or electrical wires. For example, the passivation layer 22 isolates these components from a sample that is introduced into the vicinity. This passivation layer 22 may comprise an additional layer of oxide, a non-reactive film, or other suitable coating. The passivation layer 22 may include an attachment mechanism for adherence to the MEMS structure 14 and/or to allow attachment of a hydrogel. The attachment mechanism may be physical or chemical.

An example of a chemical attachment mechanism is a cross-linking agent comprising a layer of polyglycidyl methacrylate (PGMA) partially modified with acrylic acid. A polyacrylamide (PAAm) gel may be coupled to the passivation layer via PGMA by photo or thermo initiated in situ radical copolymerization of acrylamide and N,N′-methylenebisacrylamide, thereby coupling the hydrogel to the passivation layer. The hydrogel may also be directly attached to a surface of the MEMS structure. However, this is merely an example of a method of coupling a hydrogel to a surface and claimed subject matter is not so limited.

Alternatively, the hydrogel may be attached to the MEMS structure 14 by another means that would allow the same or similar capabilities by the biosensor 10. As an example, a micropatterning process may be used for creating surfaces on the hydrogel with regions of different physical/chemical properties, although the scope of the claimed subject matter is not limited in these respects.

Biosensor 10 further includes a layer of hydrogel 24 coupled to the MEMS structure 14. As a non-limiting example, the thickness of the layer of hydrogel 24 may be selected from the ranges including: 0.1-1.0 μm; 1.0-10 μm; 10-100 μm; 100-500 μm.

Hydrogels 24 may include polymers with significant liquid content which allow them to respond to certain molecules or conditions. As non-limiting examples, such polymers include homopolymers, copolymers, oligomers, telomers, macromers, and prepolymers. Hydrogels may include probes for targeting analytes. “Probes” refer to any molecules that can bind selectively and/or specifically to an analyte. Probes include but are not limited to antibodies, antibody fragments, single-chain antibodies, genetically engineered antibodies, oligonucleotides, polynucleotides, nucleic acids, nucleic acid analogues, proteins, peptides, binding proteins, receptor proteins, transport proteins, lectins, substrates, inhibitors, activators, ligands, hormones, and cytokines.

In the absence of a target analyte, the hydrogel may be non-responsive to molecules and conditions, while in the presence of a target analyte, the hydrogels 24 may exhibit predictable characteristics such as swelling (increasing in volume). For example, one type of hydrogel 24 uses a cross-linking mechanism between probes and biomolecules in a polymer network to induce swelling of the hydrogel upon encountering an analyte. In this mechanism, the probes bond with the analyte, thereby inducing mechanical stress on the MEMS structure 14 due to steric, osmotic, and/or electrochemical effects of bonding. Hydrogels 24 may be configured with probes, reagents, and/or mechanisms other than a cross-linking mechanism for inducing stress on the MEMS structure 14 to detect a target analyte.

Hydrogels 24 may be selected for use in the biosensor 10 depending on the target analyte the biosensor is configured to detect. Further, some hydrogels 24 may be used to detect environmental conditions such as pH, temperature, chemical concentrations, electric fields, etc. (which shall all be considered analytes for purposes of this disclosure). A specific example of a pH-sensing hydrogel includes a cross-linked polymeric hydrogel composed of poly(methacrylic acid) (PMAA) with poly(ethylene glycol) dimethacrylate patterned with free-radical UV polymerization.

In another hydrogel example, an antigen-antibody semi-IPN hydrogel may be prepared by chemically modifying an antigen and antibody. The antigen used is a rabbit immunoglobulin G (IgG) and the antibody used is a goat anti-rabbit IgG (GAR IgG). By coupling them with N-succinimidylacrylate (NSA) in phosphate buffer solution, vinyl groups may be introduced into the rabbit IgG and GAR IgG. Acrylamide (AAm) is added to the vinyl (GAR IgG) along with redox initiators to synthesize polymerized GAR IgG. The vinyl (rabbit IgG), AAm, N,N′-methylenebisacrylamide (MBAA) as a crosslinker, and the polymerized GAR IgG are then copolymerized in phosphate buffer solution to form the antigen-antibody semi-IPN hydrogel. This hydrogel has an antigen-sensing function and is responsive to rabbit IgG. As additional non-limiting examples, hydrogels include interpenetrating polymer network (IPN) gels, semi-IPN gels, ionic gels, nonionic gels, hydrophobic polyelectrolyte copolymer gels, poly acrylic acid-co-isooctyl acrylate (poly(AA-co-IOA)) gels, polyacrylamide (PAAm) gels, and other mixed gels.

In one embodiment, upon introducing a sample with analytes to the biosensor 10 and waiting a period of time, the hydrogel 24 swells in response to the analytes, thus creating stress in the coupled MEMS structure 14, which may be detectable by stress sensors 20 as discussed, above. A predetermined period of time may be allotted for the sample and hydrogel 24 to react and/or equilibrate before a reading is obtained.

In one or more embodiments, there may be a predetermined proportional relationship between the hydrogel 24 swelling and the quantity and/or concentration of the analyte in the sample. There may also be a predetermined proportional relationship between the hydrogel 24 swelling and the stress created in the MEMS structure 14. The stress on the MEMS structure 14 may be detected by the embedded stress sensor(s) 20. The biosensor 10 uses the above-mentioned proportional relationships and readings from the embedded stress sensor(s) 20 for information processing to determine the quantity and/or concentration of the analyte in the sample.

In one aspect, the hydrogel 24 volume change due to the presence of the analyte significantly amplifies the stresses that are detectable by the stress sensors 20. Thus, higher sensitivity and greater data repeatability may be achieved.

In one embodiment, the physical or chemical reaction between the hydrogel 24 and the analyte may be reversible. Through desorption or other means, the analyte may be removable from the hydrogel. The hydrogel may shrink gradually in the absence of the analyte. Upon separation of the hydrogel 24 and analyte, the hydrogel returns to its original form and no longer imparts stress on the MEMS structure. The biosensor may reuse the hydrogel to detect the analyte. As a non-limiting example, the antigen-antibody semi-IPN hydrogel as described above is a reversible swelling hydrogel.

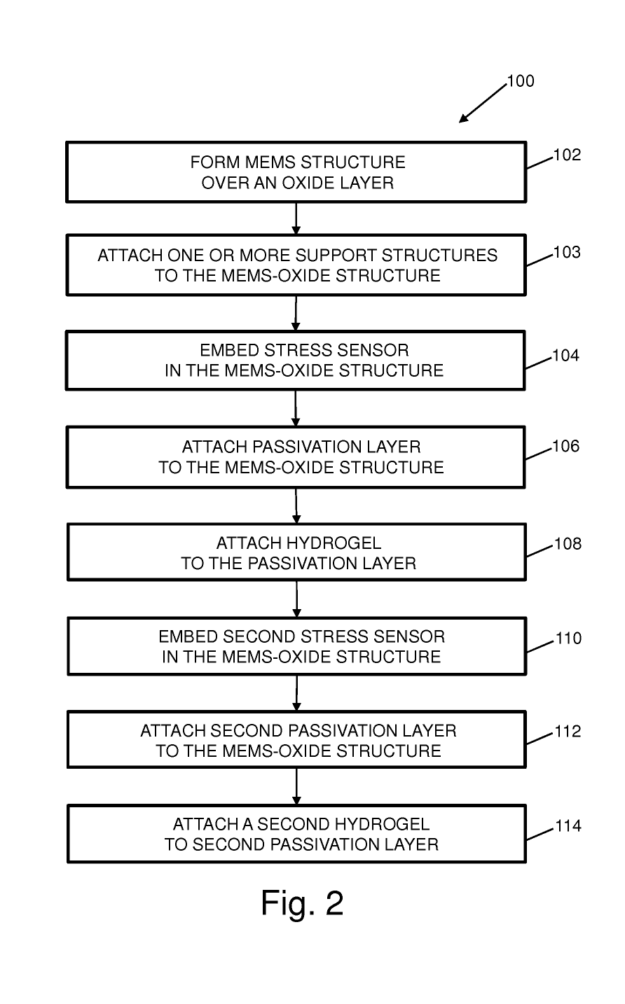

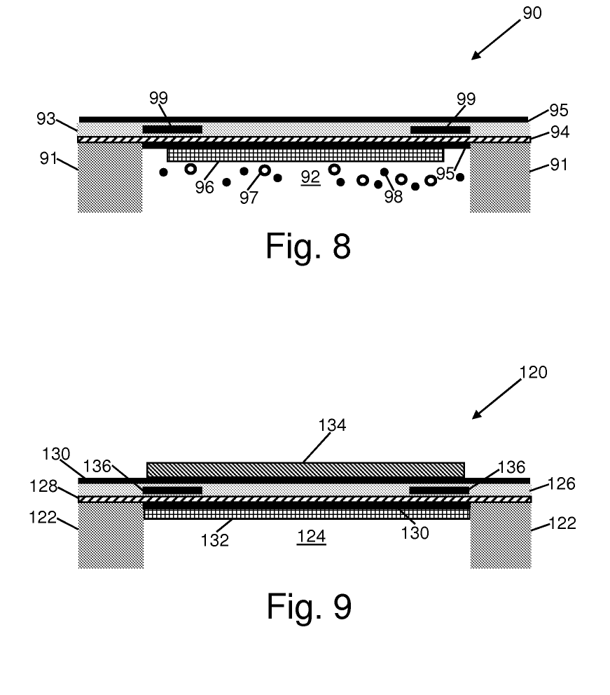

Referring to FIG. 2, a flowchart of a method of constructing a biosensor according to one embodiment is shown at 100. The method 100 includes, at 102, forming a MEMS structure over an oxide layer, thus creating a MEMS-oxide structure. At 103, the method includes coupling one or more support structures to the MEMS-oxide structure to allow for deflection. At 104, method 100 includes embedding a stress sensor in the MEMS-oxide structure at a stress-bearing location on the MEMS-oxide structure, where the stress sensor may be a FET device or piezoresistive device. At 106, the method includes attaching a passivation layer to the MEMS-oxide structure. The method further includes, at 108, attaching a hydrogel to the passivation layer. It should be noted that, at 106 and 108, the passivation layer and the hydrogel may be applied to the top of the MEMS-oxide structure or to the bottom of the MEMS-oxide structure (in the cavity), as further described in FIG. 8 below.

Method 100 may further include, at 110, embedding a second stress sensor at a second stress-bearing location on the MEMS-oxide structure. This may be more useful when the MEMS structure is a beam or a plate. Readings from the first and/or second stress sensors may be used to compute stress imparted on the MEMS-oxide structure by the hydrogel. Method 100 may include embedding additional stress sensors at various stress-bearing locations.

It should be noted that as depicted in method 100 and the disclosed embodiments, the stress sensor(s) is embedded in the MEMS structure. Alternatively, the stress sensor(s) may be embedded in the oxide layer, adjacent to the MEMS structure. When referring to embedded stress sensor(s) in the MEMS-oxide structure, the stress sensor(s) may be embedded in either location.

Method 100 may further include, at 112, attaching a second passivation layer to the MEMS-oxide structure. The method may further include, at 114, attaching a second hydrogel sensitive to a second analyte to the second passivation layer. It should be noted that, at 112 and 114, the second passivation layer and the second hydrogel may be applied to whichever of the top of the MEMS-oxide structure or the bottom of the MEMS-oxide structure (in the cavity) that had not been applied at 106 and 108. Thus, the hydrogel and the second hydrogel may sandwich the MEMS-oxide structure, as further described in FIG. 9 below.

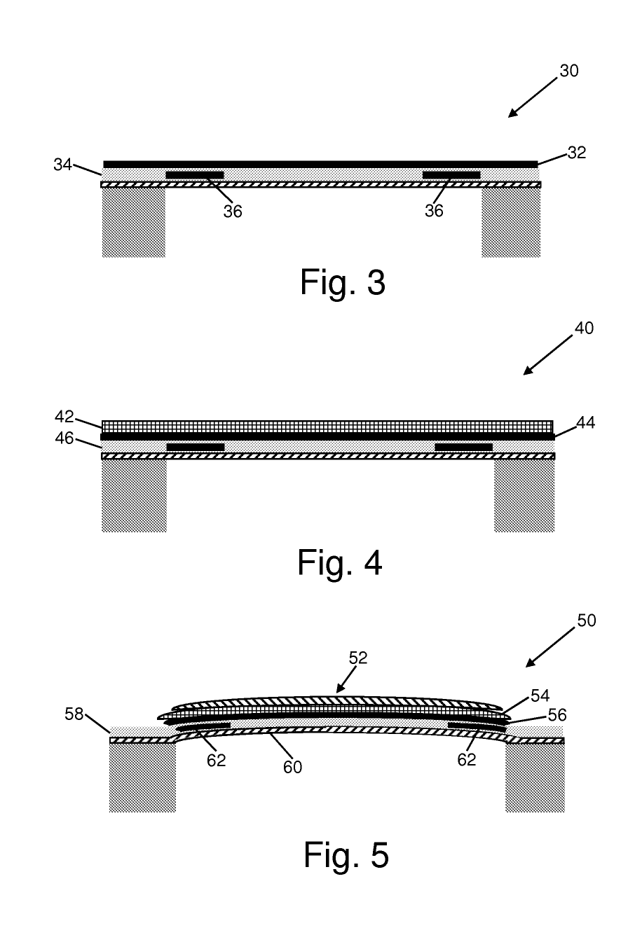

In FIG. 3, a pictorial depiction of block 106 of FIG. 2 is shown at 30. The figure shows the application of a passivation layer 32 on top of the MEMS structure 34 with embedded stress sensors 36. FIG. 4 is a pictorial depiction of block 108 of FIG. 2 at 40. The figure shows the application of a hydrogel 42. Typically, the hydrogel is uniformly applied on top of the passivation layer. Alternatively, the hydrogel may be applied to a select portion of passivation layer 44 or directly on the surface of the MEMS structure 46.

Referring to FIG. 5, a depiction of a biosensor with an analyte 52 present according to one embodiment is shown at 50. When the analyte 52 is present, the hydrogel 54 reacts by swelling and causes the attached underlying layers which may include a passivation layer 56, a MEMS structure 58, and oxide layer 60 to deflect or bend (creating stress). When the MEMS structure 58 deflects, stress sensors 62 embedded in the MEMS structure detect stress due to the modulation in conductivity which generates a conductivity signal.

It should be noted that the bending profile as depicted may vary due to variations in implementation. For example, as previously mentioned, the hydrogel 54 may be placed on a selected portion of the MEMS structure 58 and not distributed uniformly. Due to the selective placement location of the hydrogel 54, the MEMS structure 58 may be tailored to bend accordingly, thus yielding a different bending profile along one or more dimensions of MEMS structure 58. As another example, a sample including analytes may be introduced to the hydrogel 54 at a particular placement location (such as asymmetrically on one side of the MEMS structure 58), causing the MEMS structure 58 to bend accordingly, thus yielding yet another different bending profile. Such a tailored bending profile may be detected, for example, by the resulting varying outputs of stress sensors 62 at different locations of MEMS structure 58.

The amount of deflection may also depend on a variety of factors, such as dimensions and composition of the MEMS structure 58, analyte concentration, temperature, pressure, etc. For example, under load, a thinner MEMS structure 58 may bend more than a thicker MEMS structure 58. As non-limiting examples, the thickness of the MEMS structure 58 may be selected from the ranges including: 0.1-1.0 μm; 1.0-10.0 μm; 10-50 μm; 50-100 μm; 100-200 μm. The length, width, and diameter of the MEMS structure 58 may be selected from the ranges including: 1.0-10.0 μm; 10-100 μm; 100-1000 μm; 1000-10000 μm; although the scope of the claimed subject matter is not limited in these respects. In a particular embodiment, the MEMS structure 58 is a clamped-clamped beam with thickness of 25 μm, width of 50 μm, and length of 500 μm.

As depicted in FIG. 5, the analyte is present in a liquid sample such as a gel, which may be directly applied to the hydrogel 54 surface on the MEMS structure 58. Alternatively, the sample may be introduced in solid or gas form. The analyte will interact upon contact with the hydrogel.

Further, when the sample is removed, and the analyte is separated from the hydrogel 54, the hydrogel 54 may return to its original volume (reversibility in swelling). With the stress from the hydrogel 54 removed, the underlying layers of the biosensor 50, including the MEMS structure 58 or any portion thereof, may return to its original position with little or no deflection.

Turning to FIG. 6, a biosensor according to another embodiment is shown at 70. Biosensor 70 includes a pillar 71 supporting a cantilever-type MEMS structure 72 from one side. The biosensor may include a layer of oxide 73 between the pillar and the MEMS structure. The biosensor may also include a passivation layer 74 above the MEMS structure. A hydrogel layer 75 is coupled to MEMS structure 72 and is receptive to a target analyte (not shown). A stress sensor 76 is embedded in the MEMS structure and is positioned on the MEMS structure where the stresses are the highest. The principle and operation is similar to the above-described embodiment.

FIG. 7 shows the top view of yet another embodiment of a biosensor at 80. Biosensor 80 includes a plate-type MEMS structure 82 with embedded stress sensors 84. MEMS structure 82 includes a cavity below (not shown) and is held up by a support structure 86 all around the edges of the MEMS structure. Alternatively, a plurality of support structures may be constructed to support the plate-type MEMS structure. A hydrogel layer (not shown) is coupled to the MEMS structure. The MEMS structure can deflect due to stresses caused by hydrogel swelling and the stress sensors can detect those stresses. The principle and operation is similar to the above-described embodiments.

It should be noted that the plate may be in any feasible shape. Further, the stress sensors may be located anywhere on the MEMS structure. Here, there are four stress sensors located at the four corners of the plate. In general, locating the stress sensors near the support structures may provide the greatest stress differential for detection. In addition, the number of stress sensors and placement may be optimized based on the plate shape.

Turning to FIG. 8, a biosensor according to yet another embodiment is shown at 90. Biosensor 90 includes two or more support structures such as pillars 91 creating a cavity 92 in between and supporting a beam-type MEMS structure 93. The biosensor may include a layer of oxide 94 sandwiched between the pillars and the MEMS structure. The biosensor may also include a passivation layer 95 underneath the MEMS structure and/or above the MEMS structure. A hydrogel 96 is located in the cavity and coupled to MEMS structure 93. The hydrogel is configured to be receptive to a target analyte 97 in a sample in solid, liquid, or gas form.

In one embodiment, target analyte 97 is in a gaseous sample including other gas molecules 98. To test for the target analyte, the sample is introduced into cavity 92 to react with the hydrogel. As shown, the sample may be substantially contained within the cavity until the target analyte in the sample reacts with the hydrogel.

Upon encountering the analyte, the hydrogel will swell and deflect the MEMS structure. Stress sensors 99 are embedded in the MEMS structure and positioned on the MEMS structure where the stresses are likely high. The principle and operation is similar to the above-described embodiments, however, the bending profile of MEMS structure 93 will differ from the above-described embodiments.

Referring now to FIG. 9, a biosensor according to yet another embodiment is shown at 120. Biosensor 120 includes two or more support structures such as pillars 122 creating a cavity 124 in between and supporting a beam-type MEMS structure 126. In this embodiment, the MEMS structure 126 is clamped at both ends in vicinity of pillars 122, and forms a diaphragm in which the MEMS structure is free to deflect upward or downward. The biosensor may include a layer of oxide 128 sandwiched between the pillars and the MEMS structure. The biosensor may also include passivation layers 130 underneath the MEMS structure and above the MEMS structure.

A first hydrogel 132 is located in the cavity and coupled to MEMS structure 126. The first hydrogel is configured to be sensitive to a first target analyte in a sample in solid, liquid, or gas form, which may be introduced into cavity 124. A second hydrogel 134 is located above the MEMS structure 126, and is configured to be sensitive to a second target analyte in a sample in solid, liquid, or gas form.

It should be noted that first hydrogel 132 and second hydrogel 134 may be the same hydrogel configured to detect different analytes as introduced in different samples. As a non-limiting example, a sample introduced above the MEMS structure may have different ionic strength, pH, temperature, and/or analyte concentration from a sample introduced below the MEMS structure.

Stress sensors 136 are embedded in the MEMS structure 126 to detect stress that may be imparted on the MEMS structure. The stress sensors are located at positions that can detect the upward or downward deflection of the diaphragm of the MEMS structure 126. The arrangement and type of stress sensors may be chosen appropriately to sense tensile and compressive stresses caused by the swelling of the two different hydrogels.

When the first hydrogel encounters the first target analyte in a sample, the first hydrogel swells proportionately to the concentration of the first target analyte in the sample. This swelling imparts stress on the bottom of the MEMS structure. At the same time, when the second hydrogel encounters the second target analyte in a second sample, the second hydrogel also swells in proportion to the concentration of the second target analyte in the second sample. This swelling imparts stress on the top of the MEMS structure. The volume change of the first hydrogel may differ from the volume change of the second hydrogel. Thus, the amount of deflection caused by the second hydrogel may be different from the amount of deflection caused by the first hydrogel, causing a net deflection applied on the MEMS structure by both hydrogels. The net upward or downward deflection (stress) of the diaphragm may be analyzed through signal processing to determine analyte concentrations causing the swelling of each of the first hydrogel and the second hydrogel, thus the biosensor 120 enables differential sensing of concentrations of two different analytes.

It should be noted that although shown as such in FIG. 9, the first hydrogel and the second hydrogel do not have to be applied to the same locations along the length and width of the MEMS structure nor do they have to cover the entire surface of the diaphragm. The first hydrogel and the second hydrogel also are not required to start with identical volumes.

It is appreciated that a hydrogel-based MEMS biosensor has been explained with reference to multiple general exemplary embodiments, and that the disclosed subject matter is not limited to the specific details given above. References in the specification made to other embodiments fall within the scope of the claimed subject matter.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the claimed subject matter. The various appearances of “an embodiment,”“one embodiment,” or “some embodiments” are not necessarily all referring to the same embodiments.

If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Those skilled in the art having the benefit of this disclosure will appreciate that many other variations from the foregoing description and drawings may be made within the scope of the claimed subject matter. Indeed, the invention is not limited to the details described above. Rather, it is the following claims including any amendments thereto that define such scope and variations.

What is claimed is:

1. A biosensor comprising:
a microelectromechanical systems (MEMS) structure supported by two or more support structures, the MEMS structure including a flexible portion capable of deflection;
a hydrogel coupled to the MEMS structure and capable of changing in volume due to the presence of an analyte;
one or more stress sensors embedded in one or more stress-bearing locations on the MEMS structure;
wherein said one or more stress sensors are capable of detecting stress in the MEMS structure in response to volume change of the hydrogel in the presence of the analyte.

2. The biosensor of claim 1 wherein the MEMS structure deflects proportionally due to volume change of the hydrogel.

3. The biosensor of claim 1 wherein the MEMS structure comprises a beam or plate.

4. The biosensor of claim 1 wherein said two or more support structures form a cavity.

5. The biosensor of claim 4 wherein the hydrogel is located under the MEMS structure and inside the cavity.

6. The biosensor of claim 5 wherein a sample is introduced and substantially contained within the cavity until the analyte in the sample reacts with the hydrogel.

7. The biosensor of claim 5 further comprising a second hydrogel coupled to the MEMS structure and capable of changing in volume due to the presence of a second analyte, wherein the second hydrogel is located above the MEMS structure.

8. The biosensor of claim 7 wherein said one or more stress sensors are capable of detecting net stress in the MEMS structure in response to volume change of the hydrogel in the presence of the analyte and volume change of the second hydrogel in the presence of the second analyte.

9. The biosensor of claim 8 wherein the net stress in the MEMS structure imparted by the first hydrogel and the second hydrogel enables differential sensing of a concentration of the analyte in a sample and a concentration of the second analyte in a second sample.

10. The biosensor of claim 7 wherein the hydrogel and the second hydrogel are the same hydrogel configured to detect two different analytes.

11. The biosensor of claim 1 wherein said one or more stress-bearing locations are in proximity to one of said two or more support structures.

12. The biosensor of claim 1 wherein said one or more stress-bearing locations are situated where the MEMS structure experiences the highest, or nearly the highest, stresses.

13. The biosensor of claim 1 wherein said one or more stress sensors comprises one or more of a field-effect transistor device or piezoresistive device.

14. The biosensor of claim 1 wherein the hydrogel is capable of returning to an original volume when the analyte is separated from the hydrogel.

15. A method of constructing a biosensor, the method comprising:
forming a microelectromechanical systems (MEMS) structure over an oxide layer to create a MEMS-oxide structure;
attaching one or more support structures to the MEMS-oxide structure to allow for deflection;
embedding a stress sensor at a stress-bearing location on the MEMS-oxide structure;
attaching a passivation layer to the MEMS-oxide structure; and
attaching a hydrogel sensitive to an analyte to the passivation layer.

16. The method of claim 15 further comprising embedding a second stress sensor at a second stress-bearing location on the MEMS-oxide structure.

17. The method of claim 16 wherein the MEMS structure comprises a beam or plate.

18. The method of claim 15 wherein the stress sensor comprises a field-effect transistor device or piezoresistive device.

19. The method of claim 15 further comprising attaching a second passivation layer to the MEMS-oxide structure.

20. The method of claim 19 further comprising attaching a second hydrogel sensitive to a second analyte to the second passivation layer.

21. An analyte-sensing device comprising:
a MEMS structure supported by a support structure;
one or more of a field-effect transistor device or piezoresistive device embedded in the MEMS structure for detection of stress in the MEMS structure;
a passivation layer attached to the MEMS structure;
a hydrogel attached to the passivation layer and capable of causing at least a portion of the MEMS structure to deflect due to the presence of an analyte;
wherein the deflecting of said portion of the MEMS structure modulates the conductivity of said one or more of a field-effect transistor device or piezoresistive device, and results in a detectable stress in the MEMS structure via the modulated conductivity.

22. The analyte-sensing device of claim 21 wherein the hydrogel swells in response to the analyte and deflects said portion of the MEMS structure.

23. The analyte-sensing device of claim 22 wherein the hydrogel swelling is proportional to the deflection that is created.

24. The analyte-sensing device of claim 21 wherein the hydrogel is selected to react to a target analyte.

25. The analyte-sensing device of claim 21 wherein the detectable stress in the MEMS structure is indicative of quantity or concentration, or combinations thereof, of the analyte in a sample introduced to the hydrogel.

26. The analyte-sensing device of claim 21 wherein if the analyte is separated from the hydrogel, the hydrogel returns to an original volume and said portion of the MEMS structure returns to an original position with little or no deflection.
